(19) United States
(12) Patent Application Publication
(10) Pub. No.: US 2012/0125254 A1
(43) Pub. Date: May 24, 2012

(54) Method for Reducing the Range in Resistivities of Semiconductor Crystalline Sheets Grown in a Multi-Lane Furnace

(75) Inventors: Brian D. Kernan, Newton, MA (US); Gary J. Tarnowski, Acton, MA (US); Weidong Huang, Bolton, MA (US); Scott Reitsma, Shrewsbury, MA (US); Christine Richardson, Northborough, MA (US)

(73) Assignee: EVERGREEN SOLAR, INC., Marlborough, MA (US)

(21) Appl. No.: 12/952,288

(22) Filed: Nov. 23, 2010

(51) Int. Cl. C30B 11/02

(52) U.S. Cl. 117/78

(57) ABSTRACT

A method for reducing the range in resistivities of semiconductor crystalline sheets produced in a multi-lane growth furnace. A furnace for growing crystalline sheets is provided that includes a crucible with a material introduction region and a crystal growth region including a plurality of crystal sheet growth lanes. The crucible is configured to produce a generally one directional flow of material from the material introduction region toward the crystal sheet growth lane farthest from the material introduction region. Silicon doped with both a p-type dopant and an n-type dopant in greater than trace amounts is introduced into the material introduction region. The doped silicon forms a molten substance in the crucible called a melt. Crystalline sheets are formed from the melt at each growth lane in the crystal growth region. Co-doping the silicon feedstock can reduce the variation in resistivities among the crystalline sheets formed in each lane.

### TECHNICAL FIELD

The invention generally relates to crystalline sheet semiconductor fabrication and, more particularly, the invention relates to reducing the variation in properties of crystalline sheets fabricated in different lanes of a multi-lane crystalline sheet growth furnace.

### BACKGROUND ART

Crystalline sheet semiconductor crystals can form the basis of a variety of electronic devices. For example, Evergreen Solar, Inc. of Marlborough, Mass. forms solar cells from crystalline sheet semiconductor crystals, which Evergreen Solar designates STRING RIBBON™ crystals.

Continuous growth of silicon sheets eliminates the need for slicing bulk produced silicon to form wafers. For example, in one implementation, two filaments of high temperature material are introduced up through the bottom of a crucible which includes a shallow layer of molten silicon, known as a “melt.” A seed is lowered into the melt, connected to the two filaments, and then pulled vertically upward from the melt. A meniscus forms at the interface between the bottom end of the seed and the melt, and the molten silicon freezes into a solid sheet just above the melt. The filaments serve to stabilize the edges of the growing sheet. U.S. Pat. No. 7,507,291, which is incorporated herein by reference in its entirety, describes a method for growing multiple filament-stabilized crystalline sheets simultaneously in a single crucible. Each sheet grows in a “lane” in the multi-lane furnace. The cost of fabricating wafers is thus reduced compared to crystalline sheet fabrication in a single-lane furnace.

In a multi-lane furnace, where the lanes are arranged such that the silicon feedstock is introduced adjacent to a first lane and flows past the first and then successive lanes in a step-wise manner, each of the crystalline sheets will incorporate a different concentration of dopant elements. This variance occurs because of the difference in solubility of each dopant in the solid (crystalline sheet) and liquid (melt) phases. Each dopant is incorporated into the crystalline sheet at an amount different than that present in the melt, as measured by the segregation coefficient for the particular dopant. The segregation coefficient for most elements in Si is less than 1. The segregation coefficient is the ratio of the dopant concentration in the solidified sheet to the dopant concentration in the liquid phase. Because the segregation coefficient of dopant elements is less than one, the amount of each dopant in the crystalline sheet is less than the amount in the liquid from which it forms. With the segregation coefficient for each dopant less than one, the concentration of each dopant in the melt will initially increase as a crystalline sheet is extracted from the melt. Overtime, a steady state condition will be reached, where the concentration of the dopant in the melt is constant and the amount of dopant removed in the ribbon is equal to the amount of dopant supplied in the feedstock.

Further, this difference in solubility between solid and liquid phases causes a dopant concentration in the melt that increases with lane position from the feedstock introduction point, as the melt flows from the material introduction point through each growth lane in a generally uni-directional fashion. The difference in segregation coefficients for particular dopants causes a further variation in resistivity among crystalline sheets produced in different lanes of the furnace. The resistivity of a crystalline sheet is dependent on the net carrier concentration of dopant elements in the crystal. For example, boron and phosphorous are typical dopant elements used in silicon wafer processing. When the net carrier concentration p−n>0, the wafer is p-type, where p is the concentration of holes, and n is the concentration of electrons. When p−n<0, the silicon wafer is n-type. For low concentrations of [B] and [P], where [X] is the concentration of the element “X” in the wafer, it is common to assume that all carriers are completely ionized and that p−n=[B]−[P]. So, when [B]−[P]>0, the silicon wafer is p-type, while when [B]−[P]<0, the silicon wafer is n-type. Because of the difference in segregation coefficients, boron will be extracted from the melt to the crystalline sheet in higher amounts than phosphorous. This means that when [P] is very small, for crystalline sheets grown in the lane closest to the silicon feedstock introduction point, [B]−[P] will be smaller than [B]−[P] for crystalline sheets grown in the lane farthest from the feedstock introduction point. The resulting profile for dopant concentration in the melt will cause a range in resistivities for sheets produced in different lanes, which, when the sheet is processed into a photovoltaic solar cell, can affect the efficiency of light conversion into electricity for each sheet.

### SUMMARY OF PREFERRED EMBODIMENTS OF THE INVENTION

In an embodiment of the invention, crystalline semiconductor sheets are grown in a multi-lane furnace. The furnace includes a crucible configured with a material introduction region and a crystal growth region including a plurality of crystal sheet growth lanes. The crucible is configured to produce a generally one directional flow of material from the introduction region toward the crystal sheet growth lane farthest from the material introduction region. Silicon co-doped with a p-type dopant and an n-type dopant is received at the material introduction region. The ratio of the concentration by weight of the n-type dopant to the p-type dopant exceeds 0.1. The doped silicon forms a melt in the crucible and p-type crystalline sheets are grown from the melt in at least one crystalline sheet growth lane. Co-doping the silicon with appropriate levels of the dopants can reduce the variation in resistivity among the crystalline sheets grown in the various lanes of the furnace. In a specific embodiment of the invention, the p-type dopant is boron and the n-type dopant is phosphorus and the ratio by weight of the concentration of phosphorus to boron ranges from 0.4 to 1.0. In another specific embodiment of the invention, the p-type dopant is boron and the n-type dopant is arsenic and the ratio by weight of the concentration of arsenic to boron ranges from 0.9 to 2.5.

In another embodiment of the invention, crystalline semiconductor sheets are grown in a multi-lane furnace. The furnace includes a crucible configured with a material introduction region and a crystal growth region including a plurality of crystal sheet growth lanes. The crucible is configured to produce a generally one directional flow of material from the introduction region toward the crystal sheet growth lane farthest from the material introduction region. Silicon co-doped with a p-type dopant and an n-type dopant is received at the material introduction region. The ratio of the concentration by weight of the p-type dopant to the n-type dopant exceeds 0.1. The doped silicon forms a melt in the crucible and n-type crystalline sheets are grown from the melt in at least one crystalline sheet growth lane. Co-doping the silicon with appropriate levels of the dopants can reduce the variation in resistivity among the crystalline sheets grown in the various lanes of the furnace. In a specific embodiment of the invention, the p-type dopant is gallium and the n-type dopant is phosphorus and the ratio by weight of the concentration of gallium to phosphorus ranges from 4.0 to 30.0. In another specific embodiment of the invention, the p-type dopant is gallium and the n-type dopant is arsenic and the ratio by weight of the concentration of gallium to arsenic ranges from 1.0 to 13.0.

In a further preferred embodiment of the invention, crystalline semiconductor sheets are grown in a multi-lane furnace. The furnace includes a crucible configured with a material introduction region and a crystal growth region including a plurality of crystal sheet growth lanes. The crucible is configured to produce a generally one directional flow of material from the introduction region toward the crystal sheet growth lane farthest from the material introduction region. Silicon co-doped with a p-type dopant and an n-type dopant is received at the material introduction region. The p-type dopant and the n-type dopant are present in the feedstock in greater than trace amounts. The doped silicon forms a melt in the crucible and crystalline sheets are grown from the melt in at least one crystalline sheet growth lane. Co-doping the silicon with appropriate levels of the dopants can reduce the variation in resistivity among the crystalline sheets grown in the various lanes of the furnace.

In further embodiments of the invention, any of the above described embodiments may further include a material removal region in the crucible where not less than 0.5% of the material introduced at the material introduction region is removed. Such material removal primarily reduces metallic impurities in the crystalline sheets.

### BRIEF DESCRIPTION OF THE DRAWINGS

The foregoing features of the invention will be more readily understood by reference to the following detailed description, taken with reference to the accompanying drawings, in which:

FIG. 1 schematically shows a crystalline sheet growth furnace that can implement illustrative embodiments of the invention;

FIG. 2 schematically shows a partially cut away view of the growth furnace shown in FIG. 1;

FIG. 3A schematically shows a crucible configured for use with illustrative embodiments of the invention;

FIG. 3B schematically shows a crucible containing liquid silicon and growing a plurality of crystalline sheets; and

FIG. 4 shows a process of forming crystalline sheets according to illustrative embodiments of the invention.

### DETAILED DESCRIPTION OF SPECIFIC EMBODIMENTS

This application is related to U.S. patent application Ser. No. 11/741,372, entitled “System and Method of Forming a Crystal,” which is incorporated by reference herein in its entirety.

In preferred embodiments of the present invention, a method reduces the variation in resistivity of semiconductor crystalline sheets produced in a multi-lane growth furnace. A furnace for growing crystalline sheets is provided that includes a crucible with a material introduction region and a crystal growth region including a plurality of crystal sheet growth lanes. The crucible is configured to produce a generally one directional flow of material from the introduction region towards the crystalline sheet growth lane farthest from the material introduction region. Silicon doped with both a p-type dopant and an n-type dopant in greater than trace amounts is introduced into the material introduction region. The doped silicon forms a molten substance in the crucible called a melt. Crystalline sheets are formed at each growth lane in the crystal growth region. Co-doping the silicon feedstock with appropriate levels of dopants can reduce the variation in resistivity among the crystalline sheets formed at each lane. The crucible may optionally have a material removal region where molten material is removed from the crucible. The crystalline sheet growth lanes are typically situated between the material removal region and the material introduction region.

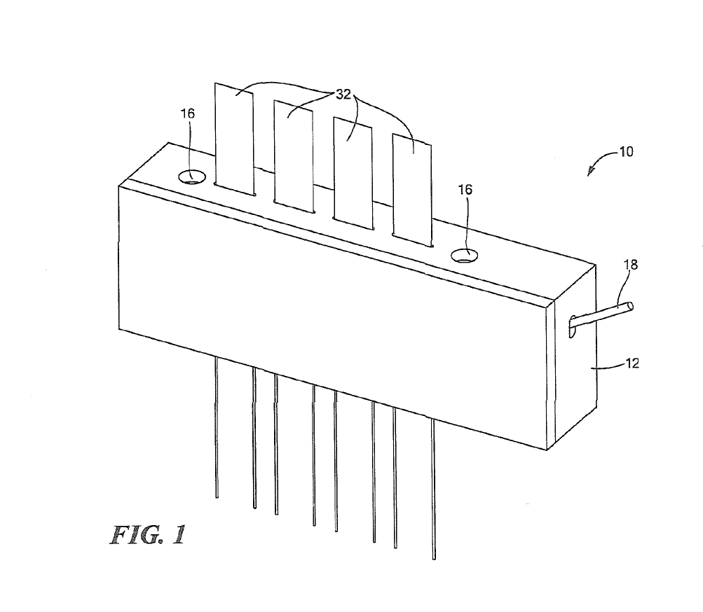

FIG. 1 schematically shows a crystalline sheet growth furnace 10 that may be used with illustrative embodiments of the invention. The furnace 10 has, among other things, a housing 12 forming a sealed interior that is substantially free of oxygen (to prevent combustion). Instead of oxygen, the interior has some concentration of another gas, such as argon, or a combination of gasses. The housing interior also contains, among other things, a crucible 14 and other components (some of which are discussed below) for substantially simultaneously growing four silicon crystalline sheets 32. The crystalline sheets 32 may be any of a wide variety of crystal types, such as multi-crystalline, single crystalline, polycrystalline, microcrystalline or semi-crystalline. A feed inlet 18 in the housing 12 provides a means for directing silicon feedstock to the interior crucible 14, while an optional window 16 permits inspection of the interior components.

It should be noted that discussion of silicon crystalline sheets 32 is illustrative. For example, the crystals may be formed from a material other than silicon, or a combination of silicon and some other material. As another example, illustrative embodiments may form non-crystalline sheets. Further, while illustrative embodiments of the invention are described with respect to a furnace with four growth lanes with the sheets generally parallel to each other in a single line, other embodiments may employ more growth lanes or fewer growth lanes and the disposition of the growth lanes with respect to each other may differ.

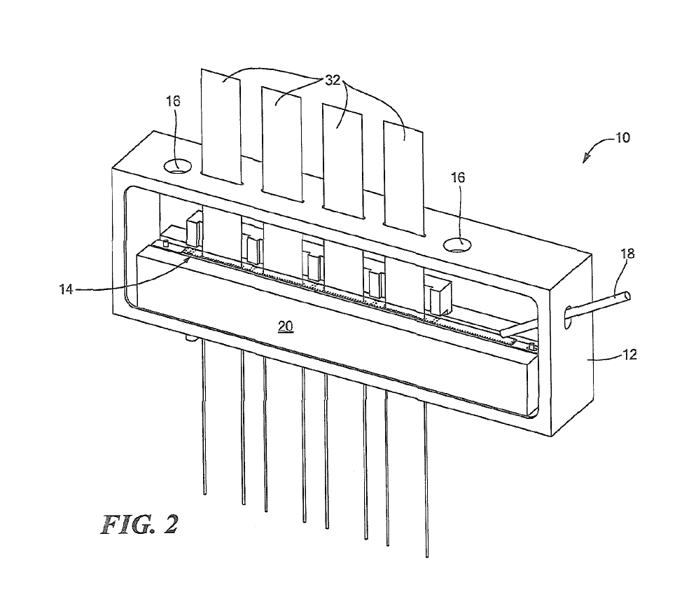

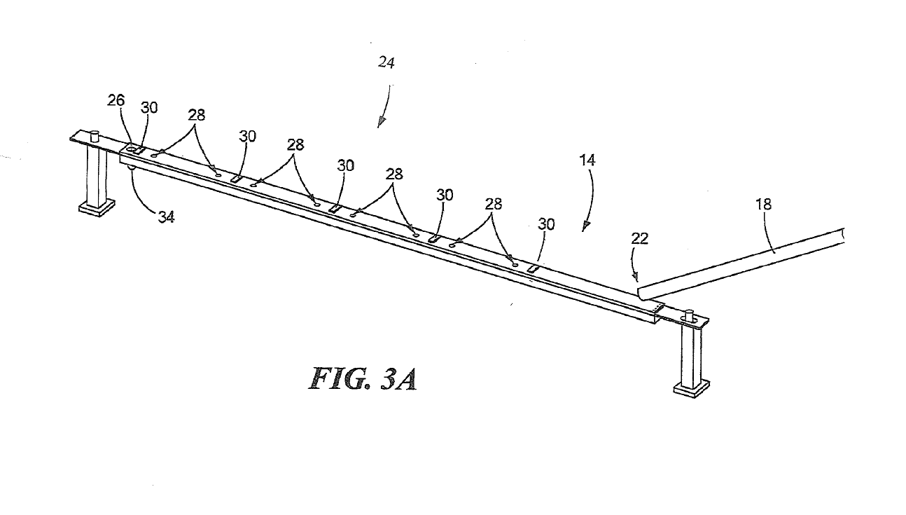

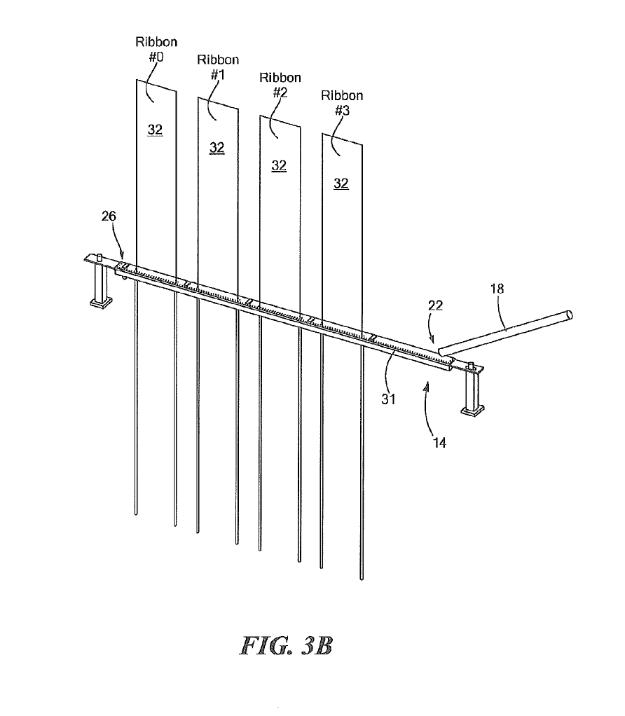

FIG. 2 schematically shows a partially cut away view of the crystalline sheet growth furnace 10 shown in FIG. 1. This view shows, among other things, the above noted crucible 14, which is supported on an interior platform 20 within the housing 12 and has a substantially flat top surface. As shown in FIG. 3A, the crucible 14 has an elongated shape with a region for growing silicon crystalline sheets 32 in a side-by-side arrangement along its length. While illustrative embodiments of the invention are described with respect to this exemplary furnace with four growth lanes with the sheets generally parallel to each other in a single line, other furnaces for use with embodiments of the invention may employ more growth lanes or fewer growth lanes and the disposition of the growth lanes with respect to each other may differ.

The crucible 14 is formed from graphite and resistively heated to a temperature capable of maintaining silicon above its melting point. To improve unidirectional liquid flow in the crucible, the crucible 14 has a length that is much greater than its width. For example, the length of the crucible 14 may be three or more times greater than its width. Of course, in other instances, the crucible 14 is not elongated in this manner. For example, the crucible 14 may have a somewhat square shape, or a nonrectangular shape.

The crucible 14 may be considered as having three separate but contiguous regions; namely, 1) an introduction region 22 for receiving silicon feedstock from the housing feed inlet 18, 2) a crystal region 24 for growing four crystalline sheets 32, and 3) a removal region 26 for removing a portion of the molten silicon contained by the crucible 14 (i.e., to perform a dumping operation). In the exemplary furnace shown, the removal region 26 has a port 34 for facilitating silicon removal. As discussed in detail below, however, other illustrative furnaces do not have such a port 34.

The crystal region 24 may be considered as forming four separate crystal sub-regions that each grows a single crystalline sheet 32. To that end, each crystal sub-region has a pair of filament holes 28 for respectively receiving two high temperature filaments that ultimately form the edge area of a growing silicon crystalline sheet 32. Moreover, each sub-region also may be considered as being defined by a pair of optional flow control ridges 30. Accordingly, each sub-region has a pair of ridges 30 that forms its boundary, and a pair of filament holes 28 for receiving filament. As shown in the FIG. 3B, the middle crystal sub-regions share ridges 30 with adjacent crystal sub-regions. Moreover, in addition to dividing the crystal sub-regions, the ridges 30 also present some degree of fluid resistance to the flow of the molten silicon, thus providing a means for controlling fluid flow along the crucible 14.

FIG. 3B schematically shows an example of a crucible 14 with shallow perimeter walls 31. In addition, this fig. shows this embodiment of the crucible 14 containing liquid silicon and growing four silicon sheet crystals 32. As shown, the crystal sub-region closest to the introduction region 22, referred to as a first sub-region, grows “sheet D,” while a second sub-region grows “sheet C.” A third sub-region grows “sheet B,” and a fourth sub-region, which is closest to the removal region 26, grows “sheet A.” As known by those skilled in the art, continuous silicon crystalline sheet growth may be carried out by introducing two filaments of high temperature material through filament holes 28 in the crucible 14. The filaments stabilize the edges of the growing crystalline sheet 32 and, as noted above, ultimately form the edge area of a growing crystalline sheet 32.

As shown in FIG. 3B, the molten silicon drawn upwardly integrates with the filament and existing frozen crystalline sheet 32 just above the top surface of the molten silicon. It is at this location (referred to as the “interface”) that the solid crystalline sheet 32 typically rejects a portion of the impurities from its crystalline structure. Among other things, such impurities may include iron, carbon, and tungsten. The impurities thus are rejected back into the molten silicon, consequently increasing the impurity concentration within the crystal region 24. During this process, each crystalline sheet 32 preferably is drawn from the molten silicon at a very low rate. For example, each crystalline sheet 32 may be pulled from the molten silicon at a rate of about one inch per minute.

The crucible 14 is configured to cause the molten silicon to flow at a very low rate from the introduction region 22 toward the removal region 26. If this flow rate were too high, the melt region underneath the growing ribbon would be subject to high mixing forces. It is this low flow that causes a portion of the impurities within the molten silicon, including those rejected by the growing crystals, to flow from the crystal region 24 toward the removal region 26.

Several factors contribute to the flow rate of the molten silicon toward the removal region 26. Each of these factors relates to adding or removing silicon to and from the crucible 14. Specifically, a first of these factors simply is the removal of silicon caused by the physical upward movement of the filaments through the melt. For example, removal of four sheets crystals 32 at a rate of 1 inch per minute, where each sheet crystal 32 has a width of about three inches and a thickness ranging between about 190 microns to about 300 microns, removes about three grams of molten silicon per minute. A second of these factors affecting flow rate is the selective removal/dumping of molten silicon from the removal region 26.

Consequently, to maintain a substantially constant melt height, the system adds new silicon feedstock as a function of the desired melt height in the crucible 14. To that end, among other ways, the system may detect changes in the electrical resistance of the crucible 14, which is a function of the melt it contains. Accordingly, the system may add new silicon feedstock to the crucible 14, as necessary, based upon the resistance of the crucible 14 and melt level. For example, in some implementations, the melt height may be generally maintained by adding one generally spherical silicon slug having a diameter of about a few millimeters about every one second. See, for example, the following United States patents (the disclosures of which are incorporated herein, in their entireties, by reference) for additional information relating to the addition of silicon feedstock to the crucible 14 and maintenance of a melt height: U.S. Pat. No. 6,090,199, U.S. Pat. No. 6,200,383, and U.S. Pat. No. 6,217,649.

The flow rate of the molten silicon within the crucible 14 therefore is caused by this generally continuous/intermittent addition and removal of silicon to and from the crucible 14. It is anticipated that at appropriately low flow rates, the geometry and shape of various forms of the crucible 14 should cause the molten silicon to flow toward the removal region 26 by means of a generally one-directional flow. By having this generally one directional flow, the substantial majority of the molten silicon (substantially all molten silicon) flows directly toward the removal region 26.

### Feedstock Co-Doping

In a multi-lane crystalline sheet growth furnace, such as the furnace described above, silicon feedstock is frequently procured with only trace levels of p-type and n-type dopants. The feedstock is conventionally doped with either a p-type dopant to create p-type crystalline sheets or an n-type dopant to produce n-type crystalline sheets. For example, silicon feedstock can be doped with the p-type dopant boron, prior to introduction to the crucible, to generate p-type crystalline sheets. Note that doping feedstock with more than one dopant type (i.e. co-doping) has not generally been performed because, among other reasons known to the inventors, co-doping incurs additional costs compared to single dopant methods.

For a four lane furnace with silicon feedstock introduced with:
boron (p-type dopant) concentration of about 95 part per billion by weight,
phosphorus (n-type dopant) concentration of about 0.1 parts per billion by weight (a trace amount), and
melt dump removal rate=1%,
   a simulation indicated that the resistivity of sheets grown with these parameters would be:

| | LANE D | LANE C | LANE B | LANE A |
|---|---|---|---|---|
| sheet | 2.16 | 2.04 | 1.85 | 1.46 |
| resistivity in | | | | |
| ohm-cm | | | | |

Notes:
lane D is adjacent to the material introduction region while lane A is farthest from the material introduction region. The flow of melt is generally one-way from lane D to lane A. All results given in this specification for resistivities of crystalline sheets are derived from simulations rather than physical measurements. Note also that in this specification and any appended claims, a “trace amount” of boron or phosphorus is any concentration of these dopants in the feedstock less than 10 parts per billion by weight.

The average resistivity for crystalline sheets grown in the four lanes is 1.88 ohm-cm. The resistivity decreases for sheets grown as the lane position from the material introduction region increases. This decrease in resistivity occurs because the concentration of boron in the melt increases from lane D to lane A. The increase in concentration of boron in the melt from lane to lane occurs because (1) there is generally a one-way flow of melt from lane D to lane A and (2) the segregation coefficient of boron is less than one (about 0.8). Thus, only a portion of the boron in the melt in a lane is removed by growth of the crystalline sheet in that lane. As the boron concentration in the melt increases from lane to lane, the net difference in carrier concentration in the crystalline sheets, [B]−[P], increases accordingly. The increase in [B]−[P] causes the resistivity to drop about 0.7 ohm-cm from a sheet grown in lane D to a sheet grown in lane A. The silicon feedstock can be doped with the boron dopant using any method known in the art, such as spin-coating.

A. Co-Doping Yielding P-Type Crystalline Sheets with Reduced Resistivity Range

1. Boron and Phosphorus Dopants

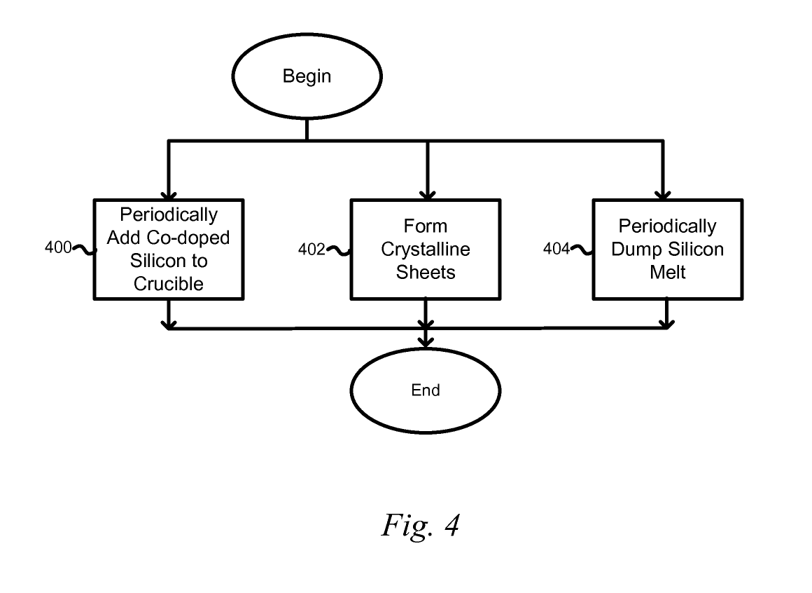

In a preferred embodiment of the invention, silicon feedstock is doped with boron and/or phosphorus as needed (i.e., co-doping) to achieve concentration ratios of P to B greater than 0.1 for p-type crystalline sheets. Doping the feedstock may be effected by any means known in the art, e.g., spin-coating, etc. FIG. 4 shows the process of adding co-doped silicon to the crucible 400, forming crystalline sheets in the lanes of the furnace 402 and, optionally, periodically dumping silicon melt from the crucible 404.

For example, for a four lane furnace with silicon feedstock introduced with:
boron (p-type dopant) concentration of about 115 ppb by weight,
phosphorus (n-type dopant) concentration of about 70 parts per billion by weight, and
melt dump removal rate=1%.

Thus, [P]/[B]=0.61 in the material introduction region.

A simulation indicated that the resistivity of sheets grown with these parameters would be:

| | LANE D | LANE C | LANE B | LANE A |
|---|---|---|---|---|
| sheet | 2.00 | 1.91 | 1.805 | 1.808 |
| resistivity in | | | | |
| ohm-cm | | | | |

While the average resistivity for sheets grown in the four lanes is the same for these conditions as for the prior simulation for the case without co-doping, the spread in resistivities for sheets grown in the four lanes is reduced to 0.19 ohm-cm, a reduction of 72%.

The presence of both the n-type dopant phosphorus and p-type dopant boron in the silicon feedstock in non-trace amounts (co-doping) works to reduce the spread in resistivities of the crystalline sheets grown in the several lanes of the furnace. As indicated above, the resistivity of the crystalline sheets grown under these conditions is dependent on the net carrier concentration, p−n≈[B]−[P], and therefore of the boron and phosphorus dopants concentrations in the crystalline sheet. Because of the difference in segregation coefficients, boron will be extracted from the melt to the crystalline sheet in higher amounts than phosphorous. Thus, as the feedstock flows in the melt from introduction near lane D towards lane A, [B]'s increase in the melt will be slower than [P]'s increase in the melt because the segregation coefficient of P is less than half the segregation coefficient of B. [P]'s swifter increase is tempered by the proper selection of the concentration of phosphorus at the introduction point compared to the concentration of boron, e.g., phosphorus is present in lower concentrations in the feedstock than boron. These two opposing factors work to reduce the variation in [B]−[P] among crystalline sheet grown in different lanes in the furnace. The above results were achieved with a melt dump removal rate of 1%, where a melt dump removal rate is the percentage of feedstock introduced at the material introduction region that is removed from the removal region of the crucible.

In other embodiments of the invention, the ratio of [P] to [B] in the feedstock can be set to a different ratio with corresponding changes in the spread of resistivities among the lanes. For example, for a four lane furnace with silicon feedstock introduced with:
boron (p-type dopant) concentration of about 115 ppb by weight, and
phosphorus (n-type dopant) concentration of about 46 parts per billion by weight, and
melt dump removal rate=1%.

Thus, [P]/[B]=0.40 in the material introduction region.

A simulation indicated that the resistivity of sheets grown with these parameters would be:

| | LANE D | LANE C | LANE B | LANE A |
|---|---|---|---|---|
| sheet | 2.07 | 1.97 | 1.83 | 1.656 |
| resistivity in | | | | |
| ohm-cm | | | | |

The average resistivity of the four lanes remains 1.88 ohm-com. While the range in resistivity is less than the range in resistivity without co-doping, the reduction is less pronounced than with [P]/[B]=0.61.

In a further example, for a four lane furnace silicon feedstock introduced with:
boron (p-type dopant) concentration of about 138 ppb by weight,
phosphorus (n-type dopant) concentration of about 138 parts per billion by weight, and
melt dump removal rate=1%.

Thus, [P]/[B]=1.0 in the material introduction region.

A simulation indicated that the resistivity of sheets grown with these parameters would be:

| | LANE D | LANE C | LANE B | LANE A |
|---|---|---|---|---|
| sheet | 1.82 | 1.76 | 1.71 | 2.25 |
| resistivity in | | | | |
| ohm-cm | | | | |

The average of resistivity of sheets grown in the four lanes remains at 1.88 ohm-com. In this case, while the range in resistivities is less than the range in resistivities without co-doping, the range reduction is also less pronounced than with a [P]/[B]=0.61. In fact, as the ratio of [P]/[B] increases beyond about 1.1 the range of resistivities can increase compared to the case with no co-doping, as the increased concentration of phosphorus in the silicon feedstock overcompensates for the lower segregation coefficient of phosphorus as compared to boron.

Note the doping levels for P and B are provided by way of example only and not by way of limitation. The levels of the co-dopants P and B can be adjusted to achieve other desired average resistivities for the crystalline sheets grown in the various lanes. Further, while the example above is for a four lane furnace, embodiments of the invention are applicable to any furnace with a plurality of crystalline sheet growth lanes. In specific embodiments of the invention, feedstock is doped so that the concentration ratio of phosphorus to boron by weight ranges from 0.4 to 1.0. All of these variations are within the scope of the invention as described in the appended claims.

2. Boron and Arsenic Dopants

In other embodiments of the invention, silicon feedstock may be doped with dopants other than phosphorus and boron to achieve p-type crystalline sheets. For example: the p-type dopant may include boron while the n-type dopant may include arsenic.

For a four lane furnace without co-doping under the following conditions with silicon feedstock introduced with:
boron (p-type dopant) concentration of about 63 ppb by weight,
arsenic (n-type dopant, trace amount only) concentration of about 0.1 ppb by weight, and
melt dump removal rate=0.5%,
   a simulation indicated that the resistivity of crystalline sheets grown with these parameters would be:

| | LANE D | LANE C | LANE B | LANE A |
|---|---|---|---|---|
| sheet | 3.2 | 3.0 | 2.7 | 2.1 |
| resistivity in | | | | |
| ohm-cm | | | | |

The average resistivity of these p-type crystalline sheets is about 2.75 ohm-cm.

For a four lane furnace with co-doping with silicon feedstock introduced with:
boron (p-type dopant) concentration of about 69 ppb by weight,
arsenic (n-type dopant) concentration of about 62 parts per billion by weight, and
melt dump removal rate=0.5%.

Thus, [As]/[B]=0.9 in the material introduction region.

A simulation indicated that the resistivity of crystalline sheets grown with these parameters would be:

| | LANE D | LANE C | LANE B | LANE A |
|---|---|---|---|---|
| sheet | 3.0 | 2.9 | 2.6 | 2.5 |
| resistivity in | | | | |
| ohm-cm | | | | |

The average resistivity for all sheets is 2.75 ohm-cm. The range of resistivities in the crystalline sheets is thus reduced by about 50% compared to forming the sheet without co-doping the feedstock.

For a four lane furnace with co-doping with silicon feedstock introduced with:
boron (p-type dopant) concentration of about 83 ppb by weight,
arsenic (n-type dopant) concentration of about 208 parts per billion by weight, and
melt dump removal rate=5%.

Thus, [As]/[B]=2.49 in the material introduction region.

A simulation indicated that the resistivity of crystalline sheets grown with these parameters would be:

| | LANE D | LANE C | LANE B | LANE A |
|---|---|---|---|---|
| sheet | 2.8 | 2.7 | 2.6 | 2.9 |
| resistivity in | | | | |
| ohm-cm | | | | |

The range of resistivities in the crystalline sheets is thus reduced by about 80% compared to forming the sheet without co-doping the feedstock. In specific embodiments of the invention, the concentration ratio of arsenic to boron dopants by weight ranges from 0.9 to 2.5.

Boron-phosphorus and boron-arsenic co-dopants for silicon are offered by way of example and not by way of limitation to show the impact of co-doping on resistivity range reducing. Reducing resistivity ranges in p-type crystalline sheets by co-doping silicon feedstock is applicable to other p-type and n-type dopant combinations. All such combinations are within the scope of the invention as described in the appended claims.

B. Co-Doping Yielding N-Type Crystalline Sheets with Reduced Resistivity Ranges

In a similar fashion, co-doping can be employed to reduce the range of resistivities among n-type crystalline sheets grown in the lanes of a multi-lane furnace.

1. Arsenic and Gallium Dopants

For example: the n-type dopant may include arsenic while the p-type dopant may include gallium in a further embodiment of the invention.

For a four lane furnace without co-doping with silicon feedstock introduced with:
arsenic (n-type dopant) concentration of about 216 ppb by weight
gallium (p-type dopant, trace amount only) concentration of about 0.1 ppb by weight, and
melt dump removal rate=1%,
   a simulation indicated that the resistivity of crystalline sheets grown with these parameters would be:

| | LANE D | LANE C | LANE B | LANE A |
|---|---|---|---|---|
| sheet | 4.4 | 3.5 | 2.4 | 0.8 |
| resistivity in | | | | |
| ohm-cm | | | | |

The average resistivity of these n-type crystalline sheets is about 2.75 ohm-cm.

In another embodiment of the invention, for a four lane furnace with silicon feedstock introduced with:

arsenic (n-type dopant) concentration of about 243 ppb by weight,

gallium (p-type dopant) concentration of about 438 ppb by weight, and

melt dump removal rate=0.5%.

Thus, [Ga]/[As]=1.8 in the material introduction region.

A simulation indicated that the resistivity of sheets grown with these parameters would be:

| | LANE D | LANE C | LANE B | LANE A |
|---|---|---|---|---|
| sheet | 4.1 | 3.5 | 2.4 | 1.4 |
| resistivity in | | | | |
| ohm-cm | | | | |

The range of resistivities in the crystalline sheets is thus reduced by about 31% compared to forming the sheet without co-doping the feedstock. The average resistivity of the sheets remains at 2.75 ohm-cm.

In another embodiment of the invention, for a four lane furnace with silicon feedstock introduced with:

arsenic (n-type dopant) concentration of about 290 ppb by weight,

gallium (p-type dopant) concentration of about 1105 ppb by weight, and

melt dump removal rate=1%.

Thus, [Ga]/[As]=3.81 in the material introduction region.

A simulation indicated that the resistivity of sheets grown with these parameters would be:

| | LANE D | LANE C | LANE B | LANE A |
|---|---|---|---|---|
| sheet | 3.6 | 3.0 | 2.1 | 2.1 |
| resistivity in | | | | |
| ohm-cm | | | | |

The range of resistivities in the crystalline sheets is thus reduced by about 59% compared to forming the sheet without co-doping the feedstock. The average resistivity of the sheets remains at 2.75 ohm-cm.

In another embodiment of the invention, for a four lane furnace with silicon feedstock introduced with:

arsenic (n-type dopant) concentration of about 513 ppb by weight,

gallium (p-type dopant) concentration of about 6265 ppb by weight, and

melt dump removal rate=5%.

Thus, [Ga]/[As]=12.2 in the material introduction region.

A simulation indicated that the resistivity of sheets grown with these parameters would be:

| | LANE D | LANE C | LANE B | LANE A |
|---|---|---|---|---|
| sheet | 3.0 | 2.5 | 2.1 | 3.4 |
| resistivity in | | | | |
| ohm-cm | | | | |

The range of resistivities in the crystalline sheets is thus reduced by about 64% compared to forming the sheet without co-doping the feedstock. The average resistivity of the sheets remains at 2.75 ohm-cm. In specific embodiments of the invention, the concentration ratio of gallium to arsenic dopants by weight ranges from 1.0 to 13.0.

2. Phosphorus and Gallium Dopants

In a similar fashion, co-doping can be employed to reduce the range of resistivities among n-type crystalline sheets grown in a multi-lane furnace where the n-type dopant may include phosphorus while the p-type dopant may include gallium.

For a four lane furnace without co-doping with silicon feedstock introduced with:
gallium (p-type dopant, trace amount only) concentration of about 0.1 ppb by weight,
phosphorus (n-type dopant) concentration of about 79 ppb by weight, and
melt dump removal rate=0.5%,
   a simulation indicated that the resistivity of crystalline sheets grown with these parameters would be:

| | LANE D | LANE C | LANE B | LANE A |
|---|---|---|---|---|
| sheet | 4.3 | 3.5 | 2.5 | 0.9 |
| resistivity in | | | | |
| ohm-cm | | | | |

The average resistivity of these n-type crystalline sheets is about 2.75 ohm-cm.

In another embodiment of the invention, for a four lane furnace with silicon feedstock introduced with:

gallium (p-type dopant) concentration of about 378 ppb by weight,

phosphorus (n-type dopant) concentration of about 90 ppb by weight, and

melt dump removal rate=0.5%,

Thus, [Ga]/[P]=4.2 in the material introduction region.

A simulation indicated that the resistivity of sheets grown with these parameters would be:

| | LANE D | LANE C | LANE B | LANE A |
|---|---|---|---|---|
| sheet | 3.9 | 3.2 | 2.4 | 1.6 |
| resistivity in | | | | |
| ohm-cm | | | | |

The range of resistivities in the crystalline sheets is thus reduced by about 33% compared to forming the sheets without co-doping the feedstock. The average resistivity of the sheets remains at 2.75 ohm-cm.

In another embodiment of the invention, for a four lane furnace with silicon feedstock introduced with:

gallium (p-type dopant) concentration of about 4955 ppb by weight,

phosphorus (n-type dopant) concentration of about 170 ppb by weight, and

melt dump removal rate=0.5%,

Thus, [Ga]/[P]=29.1 in the material introduction region.

A simulation indicated that the resistivity of sheets grown with these parameters would be:

| | LANE D | LANE C | LANE B | LANE A |
|---|---|---|---|---|
| sheet | 3.0 | 2.5 | 2.1 | 3.4 |
| resistivity in | | | | |
| ohm-cm | | | | |

The range of resistivities in the crystalline sheets is thus reduced by about 62% compared to forming the sheet without co-doping the feedstock. The average resistivity of the sheets remains at 2.75 ohm-cm. In specific embodiments of the invention, the concentration ratio of gallium to arsenic dopants by weight ranges from 4.0 to 30.0.

The gallium-phosphorus and gallium-arsenic co-dopants are offered by way of example and not by way of limitation. Reducing resistivity ranges in n-type crystalline sheets by co-doping feedstock is applicable to other p-type and n-type dopant combinations. All such combination are within the scope of the invention as described by the appended claims.

The embodiments of the invention described above are intended to be merely exemplary; and, numerous modifications will be apparent to those skilled in the art. For example, a multi-lane growth furnace need not have a material removal region and the method is applicable to other configurations of growth furnaces other than the exemplary furnace described above. All such ranges and modifications are intended to be within the scope of the present invention as defined in any appended claims.

What is claimed is:

1. A method of growing crystalline semiconductor sheets, the method comprising:
providing a crystalline sheet growth furnace, the furnace including a crucible configured with a material introduction region and a crystal growth region including a plurality of crystal sheet growth lanes, the crucible configured to produce a generally one directional flow of material from the introduction region toward the crystal sheet growth lane farthest from the material introduction region;
receiving at the material introduction region silicon doped with a p-type dopant and an n-type dopant, wherein the ratio of the concentration by weight of the n-type dopant to the p-type dopant exceeds 0.1, the doped silicon forming a melt; and
growing p-type crystalline sheets from the melt in at least two crystalline sheet growth lanes.

2. The method according to claim 1, wherein the p-type dopant includes boron and the n-type dopant includes phosphorus.

3. The method according to claim 2, wherein the ratio of the concentration by weight of the n-type dopant to the p-type dopant is in the range from 0.4 to 1.0.

4. The method according to claim 1, wherein the p-type dopant includes boron and the n-type dopant includes arsenic.

5. The method according to claim 4, wherein the ratio of the concentration by weight of the n-type dopant to the p-type dopant is in the range from 0.9 to 2.5.

6. The method according to claim 1, further including:
removing material from the crucible at a material removal region, the crystal growth region located between the material introduction region and the material removal region, wherein the percentage of material removed is not less than 0.5% of the material introduced at the material introduction region.

7. A method of growing crystalline semiconductor sheets, the method comprising:
providing a crystalline sheet growth furnace, the furnace including a crucible configured with a material introduction region and a crystal growth region including a plurality of crystal sheet growth lanes, the crucible configured to produce a generally one directional flow of material from the introduction region to the crystal sheet growth lane farthest from the material introduction region;
receiving at the material introduction region silicon doped with a p-type dopant and an n-type dopant, wherein the ratio of the concentration by weight of the p-type dopant to the n-type dopant exceeds 0.1, the doped silicon forming a melt; and
growing n-type crystalline sheets from the melt in at least two crystalline sheet growth lanes.

8. The method according to claim 7, wherein the p-type dopant includes gallium and the n-type dopant includes phosphorus.

9. The method according to claim 8, wherein the ratio of the concentration by weight of the p-type dopant to the n-type dopant is in the range from 4.0 to 30.0

10. The method according to claim 9, wherein the p-type dopant includes gallium and the n-type dopant includes arsenic.

11. The method according to claim 10, wherein the ratio of the concentration by weight of the p-type dopant to the n-type dopant is in the range from 1.0 and 13.0

12. The method according to claim 7, further including:
removing material from the crucible at a material removal region, the crystal growth region located between the material introduction region and the material removal region wherein the percentage of material removed is not less than 0.5% of the material introduced at the material introduction region.

13. A method of growing crystalline semiconductor sheets, the method comprising:
providing a crystalline sheet growth furnace, the furnace including a crucible configured with a material introduction region and a crystal growth region including a plurality of crystal sheet growth lanes, the crucible configured to produce a generally one directional flow of material from the introduction region to the crystal sheet growth lane farthest from the material introduction region;
receiving at the material introduction region silicon doped with a p-type dopant and an n-type dopant, wherein the amount of the n-type dopant exceeds a trace amount and the amount of the p-type dopant in the doped silicon exceeds a trace amount, the doped silicon forming a melt; and
growing crystalline sheets from the melt in at least two crystalline sheet growth lanes.

14. The method according to claim 13, wherein the p-type dopant includes boron and the n-type dopant includes phosphorus.

15. The method according to claim 13, wherein the p-type dopant includes boron and the n-type dopant includes arsenic.

16. The method according to claim 13, wherein the p-type dopant includes gallium and the n-type dopant includes phosphorus.

17. The method according to claim 13, wherein the p-type dopant includes gallium and the n-type dopant includes phosphorus.

18. The method according to claim 13, further including:
removing material from the crucible at a material removal region, the crystal growth region located between the material introduction region and the material removal region, wherein the percentage of material removed is not less than 0.5% of the material introduced at the material introduction region.
